(19) United States
(12) Patent Application Publication
(10) Pub. No.: US 2012/0025240 A1
(43) Pub. Date: Feb. 2, 2012

(54) PACKAGE OF LIGHT EMITTING DEVICE AND METHOD OF MANUFACTURING THE SAME

(75) Inventor: SHEN-BO LIN, Hukou (TW)

(73) Assignee: ADVANCED OPTOELECTRONIC TECHNOLOGY, INC., Hsinchu Hsien (TW)

(21) Appl. No.: 13/015,592

(22) Filed: Jan. 28, 2011

(30) Foreign Application Priority Data
Jul. 27, 2010 (CN) 201010238143.8

(51) Int. Cl. H01L 33/56

(52) U.S. Cl. 257/98; 438/27; 257/E33.059; 257/E33.062; 257/E33.072

(57) ABSTRACT

A method of manufacturing a package of light emitting device includes the following steps: providing a light emitting element and positioning the light emitting element at a bottom of a reflecting cup; providing phosphors and a compound of epoxy resin and silicone, and mixing the phosphors and the compound of epoxy resin and silicone to obtain a mixture by a process of kneading; and encapsulating the light emitting element with the mixture to form an encapsulant received in the reflecting cup.

### BACKGROUND

1. Technical Field

The present disclosure relates generally to light emitting devices, and more particularly to a package of light emitting diode (LED) and a method of manufacturing the package.

2. Description of Related Art

LEDs are solid state light emitting devices formed of semiconductors, which are more stable and reliable than other conventional light sources such as incandescent bulbs. Such LEDs emit light close to approximately single color light, which is different from light having a wide light emitting spectrum from incandescent bulbs. Recently, LED packages capable of emitting white light have been developed. A type of such white LED package is encapsulating a blue LED chip with an encapsulant where yellow phosphors are scattered. When blue light is emitted from the blue LED chip, yellow light is emitted from the yellow phosphors absorbing part of the blue light from the blue LED chip, thereby outputting white light by mixing of the blue light and yellow light. The phosphors are often powder and mixed in liquid state encapsulant. The liquid encapsulant encapsulates the LED chip by an injection process and is then baked for solidification. During baking, the phosphors are prone to deposit irregularly due to gravity. Such a deposition of the phosphors negatively impacts an optical effect of the package.

In addition, epoxy resin is generally used as the material of the encapsulant. The epoxy resin is easy to deteriorate and cause etiolation under the high temperature, which shortens lifespan of the package.

What is needed therefore is a package of light emitting device and a method of manufacturing the same which can overcome the above mentioned limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the views.

FIG. 1 is a cross sectional view of a package of a light emitting device in accordance with an embodiment of the present disclosure.

FIG. 2 is a flow chart of a method of manufacturing the package shown in FIG. 1.

### DETAILED DESCRIPTION

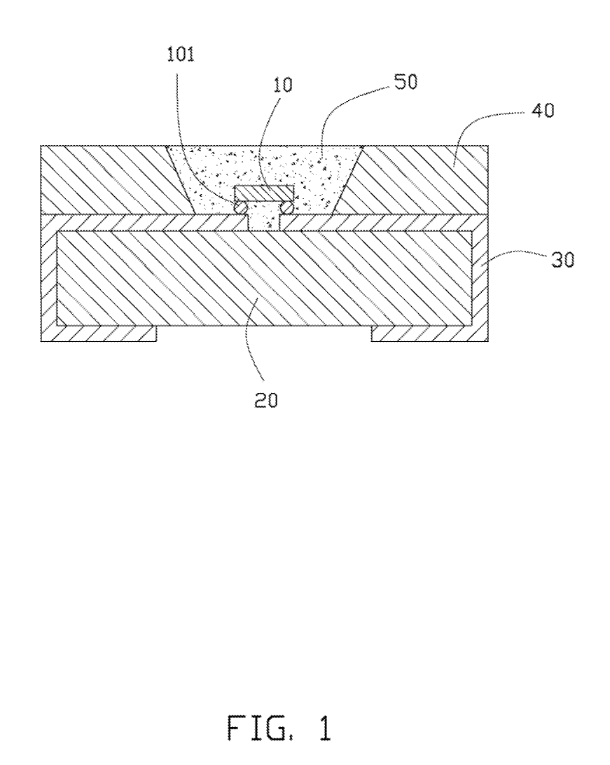

Referring to FIG. 1, the package of light emitting device includes a light emitting element 10, two electrodes 30, a reflecting cup 40 and an encapsulant 50. The light emitting element 10 is positioned at a bottom of a central recess (not labeled) defined by the reflecting cup 40 and electrically connected to the electrodes 30 by flip chip technology. The encapsulant 50 is positioned in the central recess of the reflecting cup 40 and encapsulates the light emitting element 10. The encapsulant 50 can be transparent or translucent.

The light emitting element 10 can be a nitride gallium compound semiconductor which emits light with a peak wavelength at or above 430 nm, such as a blue LED chip. The light emitting element 10 can also be a nitride gallium compound semiconductor which emits light with a peak wavelength below 430 nm, such as an ultraviolet LED chip. Two pads 101 of the light emitting element 10 electrically connect the electrodes 30 respectively, to obtain power for the light emitting element 10.

In the preferred embodiment, the light emitting element 10 is secured on a top surface of a base 20 by using flip chip technology. However, the connection is not limited thereto. The base 20 can be a mixture which includes titanium dioxide (TiO₂), hardener, and a compound of epoxy resin and silicone, and the titanium dioxide, the hardener and the compound of epoxy resin and silicone are mixed by a process of kneading. The hardener can be triethyl tetramine (TETA) or silica type hardener. The epoxy resin can be epichlorohydrin (CH₂CHOCH₂Cl), glycidol (CH₂CHOCH₂OH), etc. The silicone can be phenyl trimethylsilyl ((CH₃O)₃SiC₆H₅), etc.

The electrodes 30 can extend from the top surface of the base 20 to a bottom surface of the base 20, whereby the package is formed as a surface mounting type device.

The reflecting cup 40 can be a mixture which includes titanium dioxide (TiO₂), hardener, and a compound of epoxy resin and silicone, and the titanium dioxide, the hardener and the compound of epoxy resin and silicone are mixed by a process of kneading. The hardener can be triethyl tetramine (TETA) or silica type hardener. The epoxy resin can be epichlorohydrin (CH₂CHOCH₂Cl), glycidol (CH₂CHOCH₂OH), etc. The silicone can be phenyl trimethylsilyl ((CH₃O)₃SiC₆H₅), etc. In this embodiment, the base 20 and the reflecting cup 40 are formed integrally from a same material as a single piece.

The encapsulant 50 includes phosphors and a compound of epoxy resin and silicone, and the phosphors and the compound of epoxy resin and silicone are mixed by a process of kneading. The compound of epoxy resin and silicone is a macromolecular compound or high polymer. The phosphors can be evenly scattered in the compound of epoxy resin and silicone by kneading. The process of kneading can homogenize the compound and the phosphors, and prevent deposition of the phosphors in the compound due to gravity. The epoxy resin can be epichlorohydrin (CH₂CHOCH₂Cl), glycidol (CH₂CHOCH₂OH), etc. The silicone can be phenyl trimethylsilyl ((CH₃O)₃SiC₆H₅), etc. The phosphors can be silicon oxynitride phosphors, nitride phosphors, etc. The phosphors can be excited by absorbing light from the light emitting element 10 and emit a wavelength conversion light by converting a wavelength of the absorbed light to a light with a different wavelength.

In addition, at least one of the following can be added into the epoxy resin: hardener, accelerator, mold release agent, flame retardant, and reaction inhibitor. The hardener can be triethyl tetramine (TETA) or silica type hardener, etc. The accelerator can be platinum compounds. The mold release agent can be siloxane compounds. The flame retardant can be resins. The reaction inhibitor can be acetylene alcohol, etc.

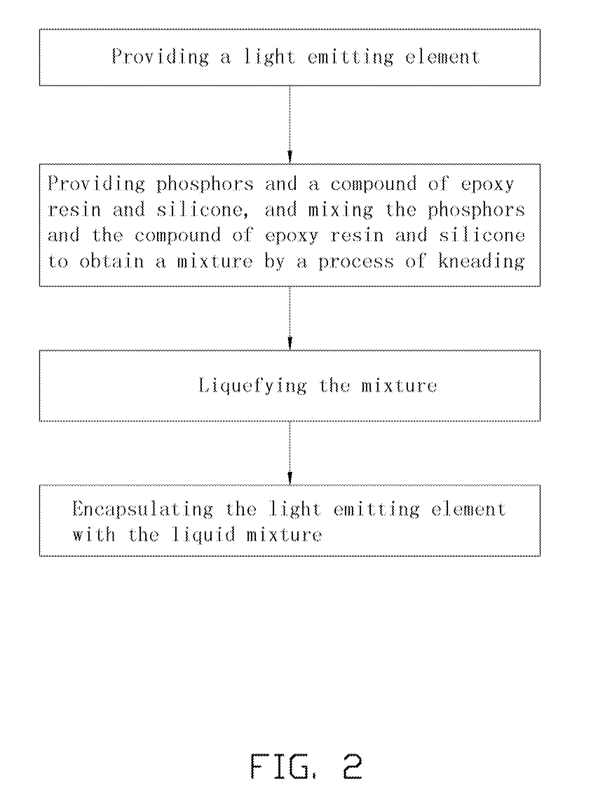

Referring to FIG. 2, a method of manufacturing the package of light emitting device in accordance with an embodiment of the present invention includes the following steps:

First, a light emitting element 10 is provided. The light emitting element 10 can be an LED chip.

Then phosphors and a compound of epoxy resin and silicone are provided. The phosphors and the compound of epoxy resin and silicone are mixed to obtain a mixture by a process of kneading.

Finally, the mixture is brought to form the encapsulant 50 which encapsulates the light emitting element 10.

Specifically, in the first step, the light emitting element 10 is mounted on the base 20. The pads 101 of the light emitting element 10 connect the electrodes 30 formed on the base 20. The base 20 can be a mixture which includes titanium dioxide (TiO₂), hardener, and a compound of epoxy resin and silicone, and the titanium dioxide, the hardener and the compound of epoxy resin and silicone are mixed by a process of kneading. After kneading, the base 20 is formed by a process of transfer molding or embedded shaping.

Further, the reflecting cup 40 can be formed on the base 20. The light emitting element 10 is positioned at the bottom of the central recesses defined by the reflecting cup 40. The encapsulant 50 is received in the reflecting cup 40. The reflecting cup 40 can be a mixture which includes titanium dioxide (TiO₂), hardener, and a compound of epoxy resin and silicone, and the titanium dioxide, the hardener and the compound of epoxy resin and silicone are mixed by a process of kneading. After kneading, the reflecting cup 40 is formed by a process of transfer molding or embedded shaping.

Specifically, in the third step, the mixture after kneading can be liquefied directly in a mold under a high temperature, and formed the encapsulant 50 in the reflecting cup 40 by a process of transfer molding. The phosphors can be coated by the compound of epoxy resin and silicone and evenly scattered in the compound of epoxy resin and silicone during the kneading, whereby deposition of the phosphors is avoided when in the process of transfer molding. Meanwhile, the fluid mixture has a larger viscosity and sustains in a fluid status for a shorter time compared with other molding processes (i.e., injection molding), which is also advantageous for anti-deposition of the phosphors in the encapsulant 50. The compound of epoxy resin and silicone as the material of the encapsulant 50 can also weaken etiolation of the encapsulant 50 under the high temperature.

In addition, at least one of the following components can also be added into the epoxy resin: hardener, accelerator, mold release agent, flame retardant, and reaction inhibitor.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A package of light emitting device comprising:
a reflecting cup;
at least two electrodes;
a light emitting element positioned in a bottom of the reflecting cup and electrically connected to the electrodes; and
an encapsulant received in the reflecting cup and encapsulating the light emitting element, the encapsulant comprising a compound of epoxy resin and silicone, and phosphors scattered in the compound.

2. The package of light emitting device of claim 1, wherein the reflecting cup is a mixture which includes titanium dioxide (TiO₂), hardener, and a compound of epoxy resin and silicone, and the titanium dioxide.

3. The package of light emitting device of claim 1, wherein the light emitting element is mounted on a base, the base being a mixture which includes titanium dioxide, hardener, and a compound of epoxy resin and silicone.

4. The package of light emitting device of claim 3, wherein the reflecting cup is integrally formed with the base as a single piece.

5. The package of light emitting device of claim 1, wherein the light emitting element is a light emitting diode.

6. A method of manufacturing a package of light emitting device comprising:
providing a light emitting element and a reflecting cup, positioning the light emitting element in a bottom of the reflecting cup;
providing phosphors and a compound of epoxy resin and silicone, and mixing the phosphors and the compound of epoxy resin and silicone to obtain a mixture by a process of kneading; and
encapsulating the light emitting element with the mixture to form an encapsulant received in the reflecting cup.

7. The method of claim 6, wherein the encapsulant is formed by a process of transfer molding.

8. The method of claim 6, wherein the reflecting cup is formed on a base, and the light emitting element is mounted on a top of the base.

9. The method of claim 8, wherein the base is integrally formed with the reflecting cup as a single piece, and is made of a mixture which includes titanium dioxide (TiO2), hardener, and a compound of epoxy resin and silicone, and the titanium dioxide, the hardener and the compound of epoxy resin and silicone being mixed by a process of kneading.

10. The method of claim 9, wherein the base and the reflecting cup are formed by a process of transfer molding or embedded shaping.

11. The method of claim 6, wherein the light emitting element is a light emitting diode.

12. The method of claim 8, wherein the light emitting element electrically connects to two electrodes formed with the base.
